(19) United States
(12) Patent Application Publication
(10) Pub. No.: US 2026/0262458 A1
(43) Pub. Date: Sep. 3, 2026

(54) SEMICONDUCTOR DEVICES WITH ELECTRICAL CONTACTS HAVING TAPERED SIDEWALLS AND METHODS OF FABRICATION THEREOF

(71) Applicant: TEXAS INSTRUMENTS INCORPORATED, Dallas, TX (US)

(72) Inventors: Jonas Hoehenberger, Kissing (DE); Michael Enzelberger-Heim, Muenchen (DE)

(21) Appl. No.: 19/067,039

(22) Filed: Feb. 28, 2025

(51) Int. Cl. H01L 21/311; H01L 21/027; H01L 21/768; H01L 23/528

(52) U.S. Cl. CPC H10P 50/73; H10P 50/287; H10P 76/2041; H10W 20/056; H10W 20/43

(57) ABSTRACT

A method includes forming a dielectric layer over a material layer over a substrate, and patterning the dielectric layer using a grayscale mask process to define an opening through the dielectric layer. The opening extends from a top surface of the dielectric layer, along a corner surface of the dielectric layer, to a side surface of the dielectric layer that intersects the material layer, wherein the top surface of the dielectric layer forms a first angle of about 90° relative to a surface normal of a top surface of the material layer, the side surface of the dielectric layer forms a second angle of about 15° or less relative to the surface normal, and the corner surface of the dielectric layer forms a third angle of about 30° or more relative to the surface normal. A metal layer is deposited over the dielectric layer including within the opening.

### TECHNICAL FIELD

The present disclosure relates to the field of semiconductor devices, and more particularly, but not exclusively, to the formation of electrical contacts in such devices.

### BACKGROUND

A semiconductor device includes one or more electrical contacts (hereinafter, simply “contact” or “contacts”) that serve the purpose of electrically connecting two or more metal components of a device. By way of example only, a contact may need to be formed in a device to electrically connect a first metal layer (e.g., a metal silicide layer covering a source, a drain, or a gate of a transistor) with a second metal layer (e.g., a metal routing layer disposed above the transistor). The first metal layer and the second metal layer can be separated by an insulating layer (e.g., a pre-metal dielectric (PMD) layer, an inter-layer dielectric (ILD) layer, an inter-layer oxide (ILO) layer, or the like) with the contact passing through the insulating layer. The contact can be formed, for example, by etching an opening in the insulating layer down to the first metal layer, filling the opening with a metal, and then forming the second metal layer over the insulating layer including over the metal-filled opening.

The sufficiency of the metal fill process (e.g., how well the metal fills the contact opening) can have a critical impact on the electrical reliability of the device. Accordingly, it is desirable to have contact formation techniques that ensure or otherwise improve metal fill sufficiency for contacts in such devices.

### SUMMARY

The present disclosure describes semiconductor devices with contacts having tapered (e.g., sloped, contoured, angled, rounded, tilted, or the like) sidewalls and methods of fabrication thereof. This summary is not an extensive overview of the disclosure. Rather, a purpose of the summary is to present some examples of the present disclosure in a simplified form as a prelude to a more detailed description that is presented later.

In one example, a method of fabricating an integrated circuit includes forming a dielectric layer over a material layer over a substrate. The method also includes patterning the dielectric layer using a grayscale mask process to define an opening through the dielectric layer. The opening extends from a top surface of the dielectric layer, along a corner surface of the dielectric layer, to a side surface of the dielectric layer that intersects the material layer, wherein the top surface of the dielectric layer forms a first angle of about 90° relative to a surface normal of a top surface of the material layer, the side surface of the dielectric layer forms a second angle of about 15° or less relative to the surface normal, and the corner surface of the dielectric layer forms a third angle of about 30° or more relative to the surface normal. The method further includes depositing a metal layer over the dielectric layer including within the opening.

In another example, a method of fabricating an integrated circuit includes forming an electronic component over a semiconductor substrate, the electronic component having a metallic terminal, and forming a dielectric layer over the metallic terminal. The method also includes patterning the dielectric layer using a grayscale mask process to form an opening through the dielectric layer from a top surface of the dielectric layer to a top surface of the metallic terminal. The opening defines a sidewall of the dielectric layer having first and second sidewall portions. The first sidewall portion extends from the top surface of the dielectric layer to the second sidewall portion and the second sidewall portion extends to the top surface of the metallic terminal. The first sidewall portion has a first tapered slope and the second sidewall portion has a second tapered slope greater than the first tapered slope. The method further includes depositing a metal routing layer over the dielectric layer, including a portion of the metal routing layer contacting the metallic terminal through the opening.

In an additional example, a semiconductor device includes an electronic device formed over a semiconductor substrate, a dielectric layer disposed over the semiconductor substrate, and a metal routing layer disposed over the dielectric layer. The semiconductor device also includes one or more metal contacts connected to the metal routing layer and extending through the dielectric layer to one or more electrical terminals of the electronic device. At least one of the metal contacts includes a sidewall having a first sidewall portion and a second sidewall portion. The first sidewall portion extends from a top surface of the dielectric layer to the second sidewall portion and the second sidewall portion extends to a top surface of a corresponding one of the electrical terminals. The first sidewall portion has a first angle of about 30° or greater relative to a surface normal from the top surface of the corresponding one of the electrical terminals, and the second sidewall portion has a second angle of about 15° or less relative to the surface normal.

### BRIEF DESCRIPTION OF THE DRAWINGS

FIG. 1 is a cross-sectional view of a semiconductor device with a contact opening having sidewalls with well-defined edges.

FIGS. 2A-2K are cross-sectional views of a process flow for forming a semiconductor device with at least one contact having tapered sidewalls in accordance with an example of the present disclosure;

FIG. 3 is a cross-sectional view of a semiconductor device with contacts having tapered sidewalls in accordance with another example of the present disclosure;

FIGS. 4A and 4B are images of cross-sectional views of respective dielectric structures having tapered sidewalls formed in accordance with examples of the present disclosure;

FIG. 5 is a flow diagram of a process for forming a semiconductor device with at least one contact having tapered sidewalls in accordance with an example of the present disclosure; and

FIG. 6 is a flow diagram of a process for forming a semiconductor device with at least one contact having tapered sidewalls in accordance with another example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent (%) of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the sufficiency of a metal fill process in the formation of a contact of a semiconductor device can have a critical impact on the electrical reliability of the device. For example, a poorly-filled metal contact can result in a higher (than expected) resistance between two components because of a lower electrical conductivity caused by the poor metal fill. Since a wide range of contact types can be used across a wide range of semiconductor devices (e.g., electronic devices, microelectromechanical structure (MEMS) devices, optical devices, or the like), the measure of the criticality with respect to the sufficiency of the metal fill process, and thus the impact on device reliability, depend on the type of device being formed. Nonetheless, it is beneficial to have contact formation techniques that ensure or otherwise improve metal fill sufficiency for contacts in any device so as to, for example, improve device reliability.

Terms such as via and interconnect can have the same or different meanings as the term contact across different devices and technologies. For example, in an integrated circuit (IC) chip context, an interconnect may refer to an electrical-connecting structure between electronic devices on a chip, a via may refer to an electrical-connecting structure between metallization layers (e.g., M1, M2, M3) of one or more electronic devices, and a contact may refer to an electrical-connecting structure between a lower metallization layer (e.g., M1) and one or more underlying electronic components (e.g., transistors, capacitors, etc.). However, in other contexts, the terms vias, interconnects, and contacts can have entirely different meanings than the example above, or the terms can have the same meanings. Accordingly, since fabrication techniques described herein in accordance with the present disclosure can be applied across a wide variety of types of electrical-connecting structures, the term contact, as used herein, is intended to broadly include vias, interconnects, and any other type or form of electrical-connecting structure that provides a conductive connection in a direction normal to a top surface of an underlying substrate.

In some contact formation approaches, a contact can be formed in a semiconductor device in the following manner. An opening is etched in an insulating layer exposing all or part of a metallic terminal of an electronic component covered by the insulating layer. The opening is then filled with a metal (e.g., tungsten) from a bottom of the opening (e.g., making an electrical connection with the exposed metallic terminal) to a top of the opening. A chemical mechanical planarization (CMP) can then be performed to remove any metal overburden and thus form a smooth top surface of the contact that is coplanar (or substantially coplanar) with a top surface of the insulating layer. In a subsequent processing step, a metal routing layer can be deposited over the top surface of the insulating layer including over the top surface of the contact.

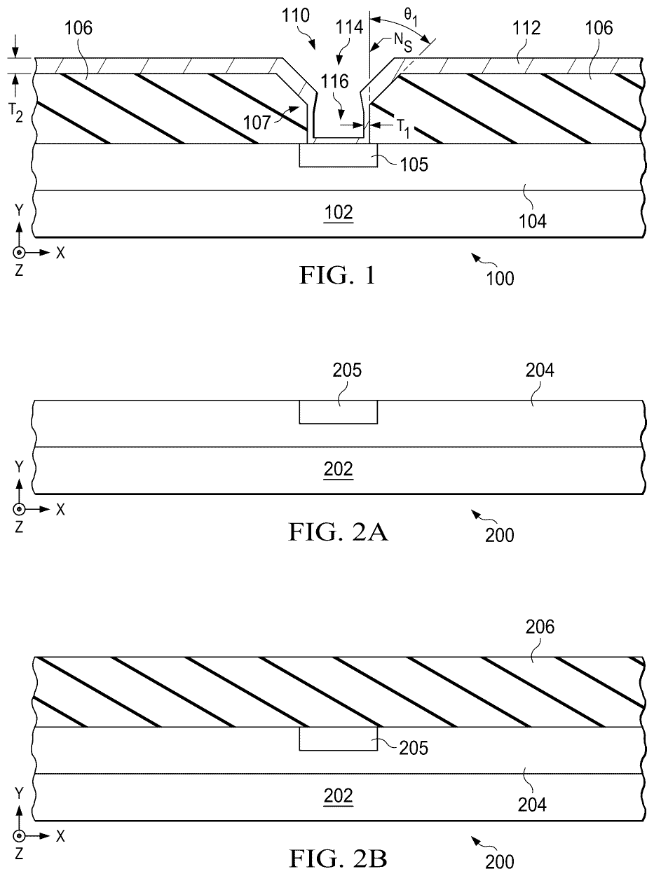

In some alternative contact formation approaches, the opening for the contact can be formed concurrently with a metal routing layer, e.g., the deposition of the metal used to form the metal routing layer on the insulating layer also fills (or at least partially fills) the opening of the contact. However, such a concurrent contact formation approach, using existing techniques, can result in poorly-filled metal contacts. For example, when sidewalls of the dielectric layer in the opening for the contact have one or more well-defined (e.g., sharp transitioning such as about 45 degrees or more) edges, the metal fill at or below such well-defined edges (e.g., on the dielectric sidewalls and/or at the bottom of the contact opening) tends to be thinner relative to the thickness of the remainder of the metal fill in the opening (e.g., the metal fill above the well-defined edge) and/or to the thickness of the metal deposited on the top surface of the dielectric layer. FIG. 1, described below, illustrates the technical challenges associated with existing techniques for forming a contact concurrently with the metal routing layer deposition.

More particularly, FIG. 1 illustrates a semiconductor device 100 in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

As shown, the semiconductor device 100 includes a substrate 102 with a semiconductor layer 104 disposed on the substrate 102, and a metallic terminal 105 of an electronic component (not expressly shown) disposed in the semiconductor layer 104. A dielectric (e.g., ILO) layer 106 is disposed on the semiconductor layer 104 with a contact opening 110 disposed in the dielectric layer 106 extending from a top surface of the dielectric layer 106 to a top surface of the metallic terminal 105. A metal routing layer 112 is disposed on the top surface of the dielectric layer 106 and partially fills the contact opening 110. Additional metal (not expressly shown) may be deposited on the metal routing layer 112 in the contact opening to form a full contact.

In existing contact fabrication processes, the contact opening 110 is formed from a combined process of a wet etch step (e.g., a liquid chemical etch) that forms a first portion 114 of the contact opening 110 followed by a dry etch step (e.g., a plasma etch such as a reactive ion etching (RIE), a dry vapor phase etch, etc.) that forms a second portion 116 of the contact opening 110. As a result of the wet etch step, the sidewalls of the dielectric layer 106 that define the first portion 114 of the contact opening 110 are formed at a substantially constant angle Θ₁ (relative to a surface normal Nₛ) of about 45 degrees, while the dry etch step results in the sidewalls of the dielectric layer 106 that define the second portion 116 of the contact opening 110 being vertical or substantially vertical (e.g., parallel to the surface normal Nₛ). One reason for beginning with the wet etch step when forming the contact opening 110 is to increase the critical dimension (CD) of the contact opening 110, while reducing the otherwise very sharp transition (e.g., about 90 degrees) that would otherwise occur between the top surface of the dielectric layer 106 and its sidewalls within the contact opening 110.

However, the ratio between the wet etch and dry etch (e.g., how long to perform the wet etch step before transitioning to the dry etch step, and then how long to perform the dry etch step) is typically difficult to control and, moreover, still results in a relatively sharp transition (e.g., about 45 degrees or more), e.g., a well-defined edge 107, along the sidewalls of the dielectric layer 106 in the contact opening 110. As further shown in FIG. 1, the well-defined edge 107 may cause an overhang of the metal deposited in the contact opening 110 at the point of the sharp transition that shadows sidewalls of the contact opening 110 resulting in a reduced metal thickness T₁ (relative to the remainder of the metal routing layer 112, e.g., thickness T₂) along the sidewall below the well-defined edge 107, as well as at the bottom of the contact opening 110 on the top surface of the metallic terminal 105.

Moreover, another technical drawback of the wet etch step is that the longer the wet etching persists, the greater chance of undercutting the sidewalls of the dielectric layer 106 in the contact opening 110. For example, in a case where the dielectric layer 106 is a combination of stacked layers including a phosphosilicate polymer such as a spin-on-glass (SOG) dielectric material (e.g., ACCUGLASS P-5S), the SOG dielectric material is particularly susceptible to unwanted etching from one or more chemical etchants of the wet etch step—e.g., resulting in undercutting portions of the dielectric sidewalls.

Accordingly, both the relatively thinner metal routing layer 112 formed on the sidewalls of the dielectric layer 106 beneath the well-defined edge 107 and on the bottom of the contact opening 110, and any dielectric sidewall undercuts caused by the wet etch step, may adversely affect the electrical conductivity of the full contact (not expressly shown in FIG. 1) formed in contact opening 110. As a result, the corresponding semiconductor device may pose unacceptable reliability risks. By way of example only, poorly-formed metal contacts in semiconductor devices can lead to inconsistent electrical properties over time and under a variety of operating conditions, which can thus cause signal degradation, increased resistance, and potential failure of the semiconductor device.

To address the above and other technical challenges in contact formation in semiconductor devices, examples of the present disclosure describe semiconductor devices with contacts having tapered sidewalls that, inter alia, reduce or eliminate well-defined or sharp transitions (e.g., about 45 degrees or more), and methods of fabrication thereof. While examples of the disclosure may be expected to provide improvements such as may be described herein, unless otherwise stated no particular result is a requirement unless explicitly recited in a particular claim.

In one example, a method of fabricating an integrated circuit includes forming a dielectric layer over a material layer over a substrate. The method also includes patterning the dielectric layer using a grayscale mask process to define an opening through the dielectric layer. The opening extends from a top surface of the dielectric layer, along a corner surface of the dielectric layer, to a side surface of the dielectric layer that intersects the material layer, wherein the top surface of the dielectric layer forms a first angle of about 90° relative to a surface normal of a top surface of the material layer, the side surface of the dielectric layer forms a second angle of about 15° or less relative to the surface normal, and the corner surface of the dielectric layer forms a third angle of about 30° or more relative to the surface normal. The method further includes depositing a metal layer over the dielectric layer including within the opening.

In some examples, the corner surface is substantially planar. In some other examples, the metal layer has a first thickness at a bottom of the opening and a second thickness over the corner surface that differs from the first thickness by no more than ±10%. In further examples, the metal layer has a first thickness over the top surface of the dielectric layer and a second thickness over the corner surface that differs from the first thickness by no more than ±5%. In some other examples, the corner surface may include a curved portion with a radius of curvature in a range from about 0.4 micrometers (μm) to about 4 μm.

The patterning of the dielectric layer may further include, in some examples, exposing a photoresist layer using a grayscale photomask that defines the opening. Moreover, in some examples, the dielectric layer is removed only by a dry etch process to form the opening. In still other examples, the metal layer completely fills the opening. In some examples, the etch rate of the photoresist layer is different than the etch rate of the dielectric layer.

In another example, a method of fabricating an integrated circuit includes forming an electronic component over a semiconductor substrate, the electronic component having a metallic terminal, and forming a dielectric layer over the metallic terminal. The method also includes patterning the dielectric layer using a grayscale mask process to form an opening through the dielectric layer from a top surface of the dielectric layer to a top surface of the metallic terminal. The opening defines a sidewall of the dielectric layer having first and second sidewall portions. The first sidewall portion extends from the top surface of the dielectric layer to the second sidewall portion and the second sidewall portion extends to the top surface of the metallic terminal. The first sidewall portion has a first tapered slope and the second sidewall portion has a second tapered slope greater than the first tapered slope. The method further includes depositing a metal routing layer over the dielectric layer, including a portion of the metal routing layer contacting the metallic terminal through the opening.

In some examples, the first tapered slope of the first sidewall portion is substantially planar. In other examples, the first tapered slope of the first sidewall portion includes an angle of greater than about 30° relative to a surface normal of the top surface of the metallic terminal, and the second tapered slope of the second sidewall portion includes an angle of less than about 15° relative to the surface normal. In further examples, the first tapered slope of the first sidewall portion is curved having a radius of curvature in a range from about 0.4 μm to about 4 μm. Also, the dielectric layer is removed only by a dry etch process to form the opening in some examples.

In an additional example, a semiconductor device includes an electronic device formed over a semiconductor substrate, a dielectric layer disposed over the semiconductor substrate, and a metal routing layer disposed over the dielectric layer. The semiconductor device also includes one or more metal contacts connected to the metal routing layer and extending through the dielectric layer to one or more electrical terminals of the electronic device. At least one of the metal contacts includes a sidewall having a first sidewall portion and a second sidewall portion. The first sidewall portion extends from a top surface of the dielectric layer to the second sidewall portion and the second sidewall portion extends to a top surface of a corresponding one of the electrical terminals. The first sidewall portion has a first angle of about 30° or greater relative to a surface normal from the top surface of the corresponding one of the electrical terminals, and the second sidewall portion has a second angle of about 15° or less relative to the surface normal. In some examples, the first sidewall portion is substantially planar, while in other examples, the first sidewall portion is curved.

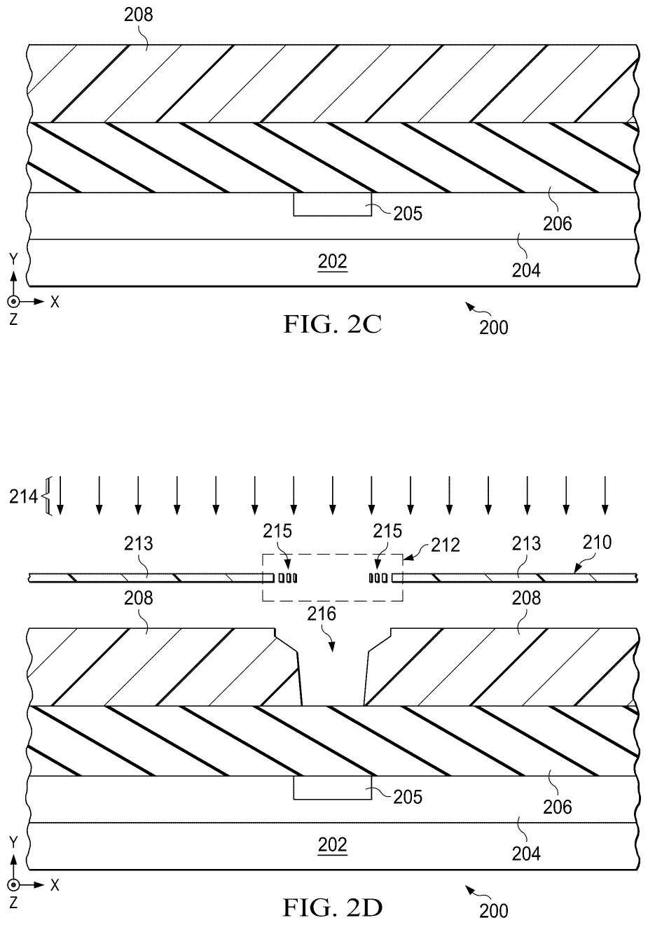

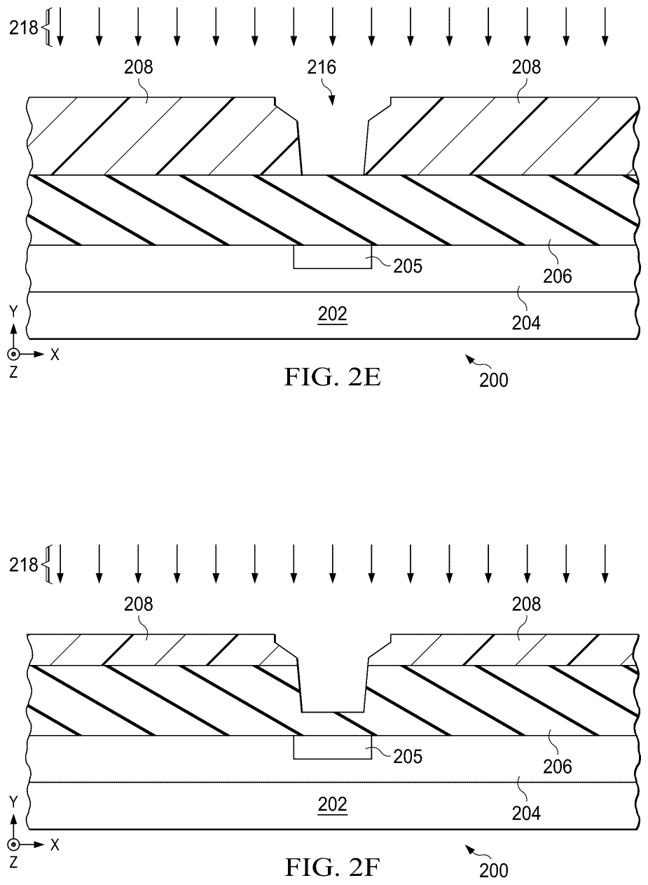

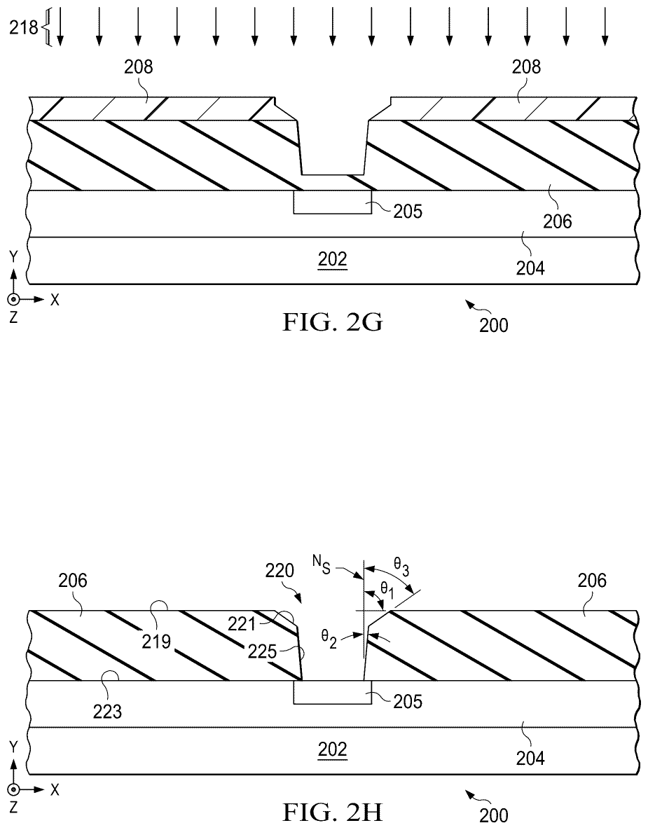

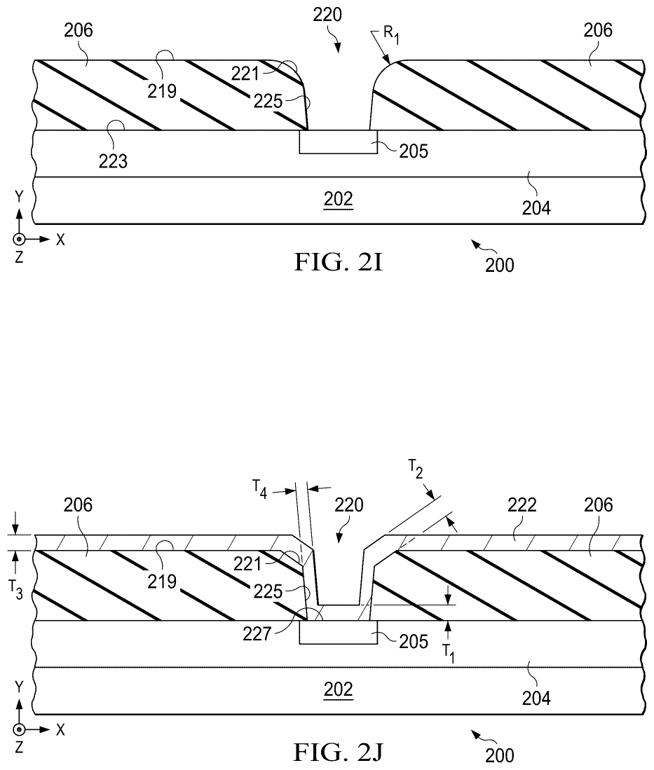

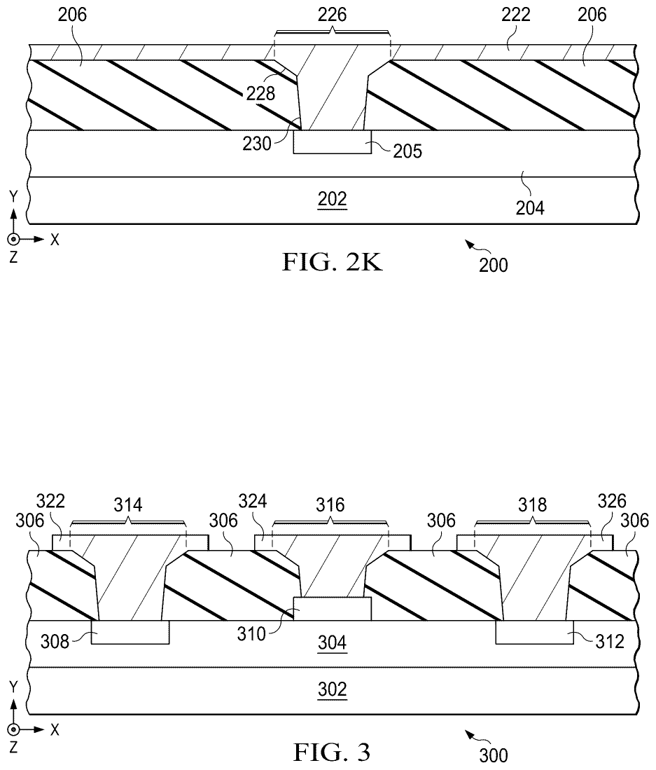

By way of one example, as will be described below in the context of FIGS. 2A-2G, a method of fabricating semiconductor devices with one or more contacts having tapered (e.g., sloped, contoured, angled, rounded, tilted, or the like) sidewalls can include the use of grayscale photolithographic techniques for patterning a tapered profile for a contact opening in a photoresist material and a dry etch process for transferring the profile for the contact opening into a dielectric layer.

While photolithographic techniques have been proposed to enable fabrication of structures with certain shapes, they have largely focused on two-dimensional (2D) shaping, e.g., mainly linear-based shapes defined in two directions on a plane where the structures have substantially perpendicular sidewalls in a third direction orthogonal to the plane. However, grayscale photolithography facilitates three-dimensional (3D) structure shaping, e.g., structures defined in two directions on a plane with non-perpendicular sidewall profiles.

More particularly, grayscale mask-based photolithography uses a mask device (e.g., also referred to as a grayscale mask device or grayscale reticle) to spatially modulate or modify a light intensity or dosage applied to a photoresist layer formed on an underlying layer of a device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the mask substrate. More particularly, grayscale mask devices rely on the concept of diffraction where light bends or spreads around the edges of the opaque areas while passing through the open areas of the patterned opaque layer. Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material) or some portion of the applied light to pass (e.g., translucent or semitransparent material).

In a clear field mask implementation, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask implementation, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The modulated light exiting the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various structures of the semiconductor device.

In some examples, the grayscale pattern features formed on the mask device include rows of pixels (e.g., square grayscale features) or sets of lines (e.g., elongate grayscale features) with each pixel row or line being spaced farther apart (or closer together, depending on the desired profile to be formed in the photoresist) from the adjacent pixel row or line. In some other examples, the width of the pixels in adjacent rows or adjacent lines may increase (or decrease) to cause the same or similar effect of modulating the spacing of the grayscale features. As such, an increasing (or decreasing) percentage of light passes through (dark field mask) or around (clear field mask) the adjacent rows of pixels or adjacent lines as they are spaced farther apart (or closer together). Regions of a mask device that include such pixels rows or lines are referred to as modulating regions, while regions of the mask device without such pixels rows or lines are referred to as non-modulating regions.

Referring now to FIGS. 2A-2K, cross-sectional views are depicted of a process flow for forming a semiconductor device 200 with at least one contact having tapered sidewalls in accordance with an example of the present disclosure.

As shown in FIG. 2A, at an intermediate stage of fabrication, the semiconductor device 200 includes a substrate 202 with a material layer, such as a semiconductor layer 204, formed on the substrate 202. In some examples, the substrate 202 includes a semiconductor wafer and the semiconductor layer 204 can be formed on the substrate 202 by an epitaxial process, wherein the semiconductor layer 204 is epitaxially grown on the substrate 202.

One or more device components (not expressly shown) can be formed in and/or on and/or over the semiconductor layer 204. Depending on the device type of semiconductor device 200 (e.g., electronic device, MEMS device, optical device, etc.), the one or more device components can include one or more electrical components, one or more mechanical components, one or more optical components, combinations thereof, and so on. Accordingly, FIG. 2A shows a metallic terminal 205 of a component formed in the semiconductor layer 204. A contact is then fabricated, as will be described below, for electrical connection with the metallic terminal 205. In other examples, the block labeled 205 can additionally or alternatively represent one or more device components or a device itself.

In one example only, metallic terminal 205 can represent a metal layer associated with a transistor (e.g., a metal silicide layer covering a source, a drain, or a gate of a transistor), a capacitor (e.g., one of the conductive plates of the capacitor), an electrical terminal of a MEMS device, an electrical terminal of an optical device, etc. Tapered contact formation techniques of the present disclosure are not intended to be limited to any particular device type, component type, or metallic terminal type and find wide applicability across any suitable semiconductor device or integrated circuit implementation.

At a next intermediate stage of fabrication, FIG. 2B shows a dielectric layer 206 formed on the semiconductor layer 204 of the semiconductor device 200 including over a top surface of the metallic terminal 205. In some examples, the dielectric layer 206 can include an insulating layer such as, for example, a PMD layer, an ILD layer, an ILO layer, or the like. In some examples, the dielectric layer 206 may be a single dielectric layer or may include multiple dielectric layers of the same dielectric material or different dielectric materials. For example, the dielectric layer 206 may include silicon nitride, a silicon oxide-based material (such as, by way of example only, a phosphosilicate glass (PSG) or a tetraethyl orthosilicate (TEOS) oxide), polytetrafluoroethylene, an SOG dielectric material (e.g., ACCUGLASS P-5S), and/or the like. Further, in some examples, a thickness (Y direction) of the dielectric layer 206 can be between about 0.3 μm to 3 μm.

As will be further described below, in the context of FIGS. 2C-2K, a contact with tapered sidewalls, in accordance with examples of the present disclosure, is formed through the dielectric layer 206 with a bottom of the contact terminating on the metallic terminal 205.

Accordingly, as shown in FIG. 2C, a photoresist layer 208 is formed across a top surface of the dielectric layer 206. Photoresist layer 208 is a light-sensitive material typically including a polymer, a sensitizer, and a solvent. The polymer changes its structure when it is exposed to radiation (e.g., light). The solvent allows the photoresist material to be spun and to form a thin layer over the target surface, e.g., the top surface of the dielectric layer 206. The sensitizer (inhibitor) controls the photochemical reaction in the polymer phase. In some examples, given that the photoresist layer 208 will be used with a grayscale photolithography process (e.g., FIG. 2D), the photoresist layer 208 can include materials such as, for example, novolak resins, diazonaphthoquinones, chalcogenide glass (ChG), as well as additional or alternative materials. Further, in some examples, a thickness (Y direction) of the photoresist layer 208 can be between about 1 μm to 5 μm.

Referring now to a next intermediate stage of fabrication of the semiconductor device 200 in FIG. 2D, a grayscale mask device 210, with a modulating region 212 and non-modulating regions 213, is disposed above the photoresist layer 208, as shown, with a light source (not expressly shown) disposed above the grayscale mask device 210. The light source directs UV light 214 onto the grayscale mask device 210. The modulating region 212 of the grayscale mask device 210 includes grayscale features 215, e.g., either pixel rows or lines as described above. The grayscale features 215, in a clear field mask implementation, serve to increasingly block the UV light 214 incident on a top surface of the grayscale mask device 210 as the grayscale features 215 become wider (or are spaced closer together) and extend away from the center of the modulating region 212 toward the opposing non-modulating regions 213. The grayscale features 215 depicted in FIG. 2D are illustrative in nature and do not necessarily represent the actual grayscale pattern used to create an underlying contact opening profile in the photoresist layer 208. Given the descriptions of the present disclosure, one ordinarily skilled in grayscale photolithography would contemplate, in a straightforward manner, the grayscale patterns needed/desired to create various underlying profiles.

Accordingly, the UV light 214 passing through the grayscale mask device 210, e.g., modulated light measured as an intensity-pass percentage, correspondingly modulates or modifies the amount of photosensitive material that is removed (e.g., for a positive photoresist) in the photoresist layer 208 to form a contact opening profile 216 in the photoresist layer 208. In a positive photoresist example, the more light that passes through the grayscale mask device 210 (e.g., higher intensity-pass percentage) onto the photoresist layer 208, the more photosensitive material of the photoresist layer is removed during development (e.g., decreasing the thickness of the photoresist layer 208 from its original thickness below the modulating region 212). By modulating the applied light in accordance with the grayscale features 215 of the modulating region 212 to change the exposure dose or intensity locally in the photoresist layer 208, the contact opening profile 216 is formed in the photoresist layer 208. As shown, a portion of the photoresist layer 208 is removed down to the dielectric layer 206 below the center of the modulating region 212 where no grayscale features 215 are present, while tapered sidewalls are formed in the photoresist layer 208 below the modulating region 212 where the grayscale features 215 are present. No portions, or negligible amounts, of the photoresist layer 208 are removed under the non-modulating regions 213.

Again, assuming a positive photoresist material in the photoresist layer 208, the photochemical reaction that occurs during exposure weakens the photoresist material making it soluble to a developer such that a positive pattern defined by the grayscale mask device 210 is formed in the photoresist layer 208—which will then be transferred in a substantially identical (or similar) form to the dielectric layer 206.

As shown in FIGS. 2E through 2H, an etch process 218 is applied to the photoresist layer 208 to transfer the contact opening profile 216 into the dielectric layer 206 to form a contact opening 220. The etch process 218 applied in accordance with the example of FIGS. 2E through 2H is a dry etch only process, as compared to the combined wet etch/dry etch process described above for forming the contact opening 110 of semiconductor device 100 (FIG. 1). Thus, no wet etch step is needed as part of the etch process 218 given that the grayscale mask device 210 (FIG. 2D) enables the tapered contact opening profile 216 to be created in the photoresist layer 208 and transferred to the dielectric layer 206 in a well-controlled manner using a dry etch process alone.

More particularly, FIGS. 2E through 2H show the progressive dry etching of the photoresist layer 208 and underlying dielectric layer 206 as the contact opening profile 216 is transferred into the dielectric layer 206 to form a contact opening 220. In some examples, it is beneficial to have a relatively high selectivity in terms of the ratio of the etch rate of the photoresist layer 208 to the etch rate of the dielectric layer 206. That is, in order to transfer the contact opening profile 216 to the dielectric layer 206 to form the contact opening 220, while substantially replicating the same profile in the dielectric layer 206, it is beneficial to etch the photoresist layer 208 at a higher rate than the dielectric layer 206—e.g., this can include a comparable but still higher rate. More generally, the dielectric layer 206 is etched at a first etch rate and the photoresist layer 208 is etched at a second etch rate different than the first etch rate.

In some examples, the etch rates for the respective materials of the dielectric layer 206 and the photoresist layer 208 can be in the range of about 50 ångströms/second (Å/sec) to 200 Å/sec. Accordingly, in one example, the etch rate for the dielectric layer 206 can be about 100 Å/sec and the etch rate for the photoresist layer 208 can be in a range approximately above 100 Å/sec to 200 Å/sec.

Controlling the etch selectivity between the photoresist layer 208 and the dielectric layer 206 can be done, in some examples, by: (i) adjusting the bias power associated with the etch process 218 (e.g., a physical approach to modulating the etch selectivity); (ii) selection of etch gases in the etch gas mixture (e.g., a chemical approach to modulating the etch selectivity); or (iii) a combination of (i) and (ii).

Bias power directly affects the energy of ions impacting the etch target during dry (e.g., plasma) etching. For example, a higher bias power leads to more energetic ions which increases the etch rate. However, while a higher bias power increases the etch rate of the photoresist layer 208, the increased ion energy (or greater ion bombardment) can cause undesired etching of the dielectric layer 206, thus reducing the difference in etch rates between the materials of the photoresist layer 208 and the dielectric layer 206—e.g., resulting in a lower etch selectivity. On the other hand, reducing bias power causes the ions to impact the etch target with less energy—e.g., resulting in a higher etch selectivity between the materials of the photoresist layer 208 and the dielectric layer 206. A tradeoff thus exists between bias power and etch selectivity-the resolution of which depends on the materials being etched and the profile being transferred from the photoresist layer to the underlying layer. In some examples, the bias power for pattern transfer can be in the range of about 600 watts (W) to 2000 W, e.g., about 1000 W.

As described above, selection of etch gases can additionally or alternatively be used to control etch selectivity between the photoresist layer 208 and the dielectric layer 206. In some examples, the etch process 218 utilizes etching agents including one or more fluorine compounds such as, by way of example only, tetrafluormethane (CF₄), trifluoromethane (CHF₃), octafluorocyclobutane (C₄F₈)+argon (Ar)+oxygen (O₂). In other examples, oxygen (O₂) and/or nitrogen (N₂) can be added as etching agents to the etch gas mixture to increase the etch rate of the photoresist layer 208 without appreciably affecting the etch rate of the dielectric layer 206. In yet another example, sulfur hexafluoride (SF₆) can be used rather than (or in conjunction with) one or more of the other fluorine compounds listed above to increase the etch rate of the photoresist layer 208 relative to the dielectric layer 206.

Accordingly, as the etch process 218 progresses from FIG. 2E through FIG. 2H, the thickness (in the Y direction) of the photoresist layer 208 decreases (e.g., the photoresist layer 208 can be completely removed) while the contact opening profile 216 is transferred into the dielectric layer 206 to form the contact opening 220 with tapered sidewalls.

In one example, FIG. 2H shows the dielectric layer 206 with tapered sidewalls defined by a set of angles Θ₁, Θ₂, and Θ₃ (e.g., tilt angles defining tapered slopes) relative to the surface normal Nₛ. As shown, contact opening 220 is defined as extending from a top surface 219 of the dielectric layer 206, along a corner surface 221 of the dielectric layer 206, to a side surface 225 of the dielectric layer 206 that intersects the semiconductor layer 204. The top surface 219 of the dielectric layer 206 forms a first angle Θ₁ of about 90° relative to the surface normal Nₛ of a top surface 223 of the semiconductor layer 204. The side surface 225 of the dielectric layer 206 forms a second angle Θ₂ of about 15° or less relative to the surface normal Nₛ. The corner surface 221 of the dielectric layer 206 forms a third angle Θ₃ of about 30° or more relative to the surface normal Nₛ. The same surfaces and angles are formed on the opposing side of the contact opening 220 of the cross-sectional view of FIG. 2H. Thus, advantageously, formation of the corner and side surfaces 221 and 225, as described herein in accordance with the present disclosure, avoids any sharp edges/transitions (e.g., about 45 degrees or greater) that would occur with a combined wet/dry etch process (e.g., as shown in FIG. 1).

In an alternative example, FIG. 2I shows the dielectric layer 206 with the corner surface 221 having a round-contoured (rounded) shape defined by a radius of curvature R₁. In some examples, the radius of curvature is in a range from about 0.4 μm to about 4 μm. The same radius of curvature is formed on the opposing side of the contact opening 220 of the cross-sectional view of FIG. 2I. Grayscale features 215 of the grayscale mask device 210 (FIG. 2D) can be implemented, in a straightforward manner, to achieve desired curvature radii.

In some examples, the contact opening 220 can have a CD width (X direction) at the top surface 223 of the semiconductor layer 204 of about 0.5 μm to 5 μm, and a CD width (X direction) at the top surface 219 of the dielectric layer 206 of greater than about 0.5 μm to 5 μm, e.g., about 0.7 μm to 10 μm. The top and bottom CDs of the contact opening 220 are a function of, for example, the selected layout of the grayscale features 215 in the grayscale mask device 210 used to create the contact opening profile 216 in the photoresist layer 208, and of the selected etch rates associated with the etch process 218.

Next, in the intermediate fabrication stage of FIG. 2J, a metal routing layer 222 is deposited on the top surface 219 of the dielectric layer 206 and within the contact opening 220. Advantageously, because the sidewalls in the contact opening 220 have no relatively sharp edges (as compared with the well-defined edge 107 of semiconductor device 100 in FIG. 1), there is no metal overhand (or significantly reduced, if any) and no thin (insufficient) sidewall coverage following the deposition of the metal routing layer 222. As such, thicknesses, e.g., a first thickness T₁, a second thickness T₂, a third thickness T₃, and fourth thickness T₄, at various locations of the metal routing layer 222 are about equal or substantially equal.

By way of example only, the first thickness T₁ at a bottom 227 of the contact opening 220 (e.g., contacting the metallic terminal 205) and the second thickness T₂ over the corner surface 221 differ by no more than ±10%. Further, in some examples, the third thickness T₃ over the top surface 219 of the dielectric layer 206 and the second thickness T₂ over the corner surface 221 differ by no more than ±5%. Lastly, in other examples, the fourth thickness T₄ over the side surface 225 differs with the second thickness T₂ over the corner surface 221 by no more than ±5%. The same thicknesses of the metal routing layer 222 are formed on the opposing side of the contact opening 220 of the cross-sectional view of FIG. 2J.

Lastly, in FIG. 2K, assuming that deposition of the metal routing layer 222 in FIG. 2J does not completely fill the contact opening 220, an additional metal fill process is performed to fill the partially filled contact opening 220 and thus form a contact 226 with tapered sidewalls (e.g., including a corner surface 228 and a side surface 230 on both sides of the contact 226). Note that the examples of angles, curvature radii, tapered slopes, etc. of the dielectric layer 206 and/or the contact opening 220 correspond to the angles, curvature radii, tapered slopes, etc. of the contact 226.

Referring now to FIG. 3, a cross-sectional view is depicted of a semiconductor device 300 with a plurality of contacts having tapered sidewalls in accordance with another example of the present disclosure. As shown, a substrate 302 has a semiconductor layer 304 disposed thereon, with a dielectric layer 306 disposed on the semiconductor layer 304. The semiconductor layer 304 has a plurality of metallic terminals 308, 310 and 312 disposed therein (e.g., metallic terminals 308 and 312) or thereon (e.g. metallic terminal 310). Further, semiconductor device 300 includes contacts 314, 316 and 318 (at least some of which have tapered sidewalls as described herein in examples of the present disclosure). The contacts 314, 316 and 318 are disposed through the dielectric layer 306 and connect with respective metallic terminals 308, 310 and 312. The contacts 314, 316 and 318 are formed by one or more respective metal fill processes that are integral with the formation of metal routing layers 322, 324 and 326.

Semiconductor device 300 can be fabricated using the same or similar fabrication steps as described above in the context of FIGS. 2A through 2K. As such, one or more of the contacts 314, 316 and 318 can be formed using a grayscale photolithographic process and a dry etch only process to form the one or more respective contact openings (not expressly shown), followed by one or more respective metal fill processes that are integral with formation of the metal routing layers 322, 324 and 326. In some embodiments, one or more of metal routing layers 322, 324 and 326, and thus contacts 314, 316 and 318, can be formed by the same metal deposition process.

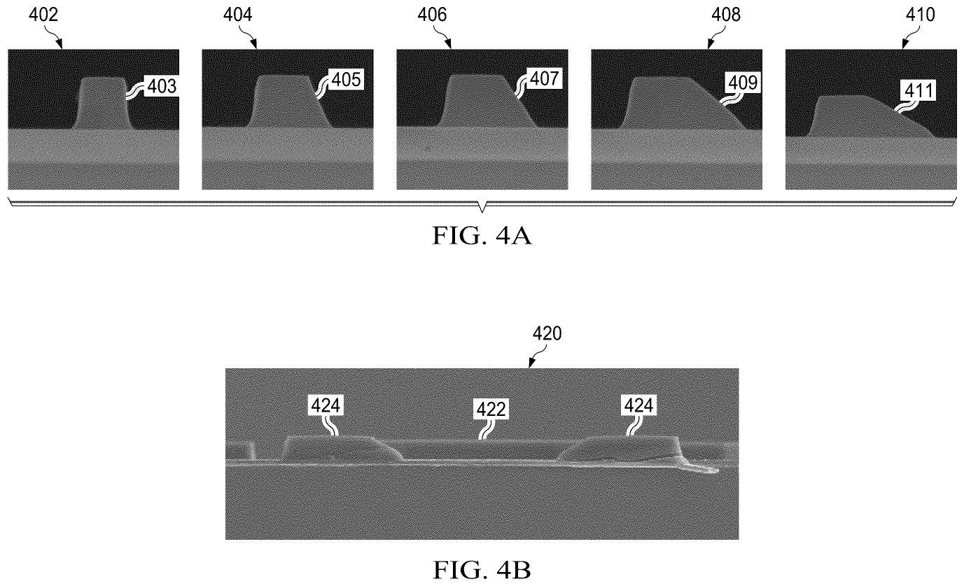

FIGS. 4A and 4B are images of cross-sectional views of respective tapered sidewalls of multiple structures formed in accordance with examples of the present disclosure. For example, in cross-sectional views of images 402, 404, 406, 408 and 410 of FIG. 4A, respective tapered sidewalls 403, 405, 407, 409 and 411 can be formed having desired tilt angles, curvature radii, etc., in accordance with contact formation techniques of the present disclosure. Likewise, FIG. 4B shows a cross-sectional view of an image 420 of a contact opening 422 with desired tapered sidewalls formed in a dielectric layer 424 in accordance with contact formation techniques of the present disclosure.

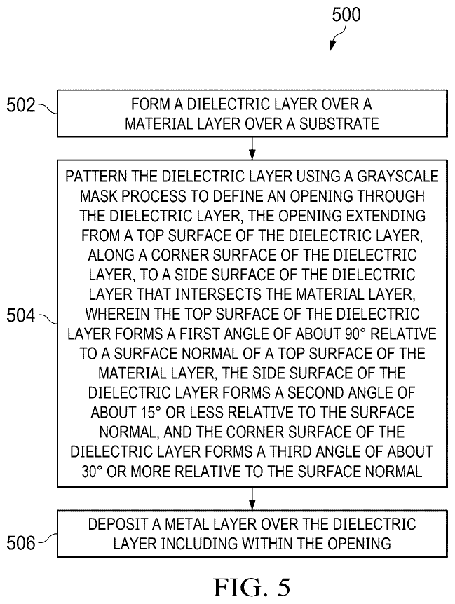

FIG. 5 is a flow diagram of a process 500 for forming a semiconductor device with at least one contact having tapered sidewalls in accordance with an example of the present disclosure. As shown, step 502 forms a dielectric layer over a material layer over a substrate. Step 504 patterns the dielectric layer using a grayscale mask process to define an opening through the dielectric layer, the opening extending from a top surface of the dielectric layer, along a corner surface of the dielectric layer, to a side surface of the dielectric layer that intersects the material layer, wherein the top surface of the dielectric layer forms a first angle of about 90° relative to a surface normal of a top surface of the material layer, the side surface of the dielectric layer forms a second angle of about 15° or less relative to the surface normal, and the corner surface of the dielectric layer forms a third angle of about 30° or more relative to the surface normal. Step 506 deposits a metal layer over the dielectric layer including within the opening.

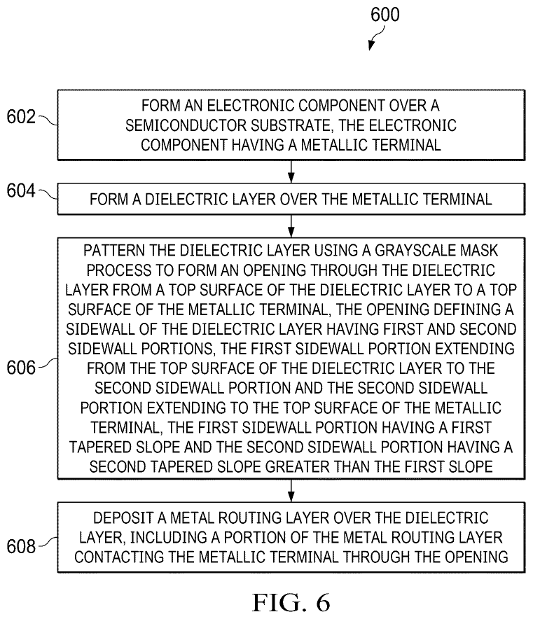

FIG. 6 is a flow diagram of a process 600 for forming a semiconductor device with at least one contact having tapered sidewalls in accordance with another example of the present disclosure. Step 602 forms an electronic component over a semiconductor substrate, the electronic component having a metallic terminal. Step 604 forms a dielectric layer over the metallic terminal. Step 606 patterns the dielectric layer using a grayscale mask process to form an opening through the dielectric layer from a top surface of the dielectric layer to a top surface of the metallic terminal, the opening defining a sidewall of the dielectric layer having first and second sidewall portions, the first sidewall portion extending from the top surface of the dielectric layer to the second sidewall portion and the second sidewall portion extending to the top surface of the metallic terminal, the first sidewall portion having a first tapered slope and the second sidewall portion having a second tapered slope greater than the first slope. Step 608 deposits a metal routing layer over the dielectric layer, including a portion of the metal routing layer contacting the metallic terminal through the opening.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method of forming an integrated circuit, comprising:
forming a dielectric layer over a material layer over a substrate;
patterning the dielectric layer using a grayscale mask process to define an opening through the dielectric layer, the opening extending from a top surface of the dielectric layer, along a corner surface of the dielectric layer, to a side surface of the dielectric layer that intersects the material layer, wherein the top surface of the dielectric layer forms a first angle of about 90° relative to a surface normal of a top surface of the material layer, the side surface of the dielectric layer forms a second angle of about 15° or less relative to the surface normal, and the corner surface of the dielectric layer forms a third angle of about 30° or more relative to the surface normal; and
depositing a metal layer over the dielectric layer including within the opening.

2. The method of claim 1, wherein the corner surface is substantially planar.

3. The method of claim 1, wherein the metal layer has a first thickness at a bottom of the opening and a second thickness over the corner surface that differs from the first thickness by no more than ±10%.

4. The method of claim 1, wherein the metal layer has a first thickness over the top surface of the dielectric layer and a second thickness over the corner surface that differs from the first thickness by no more than ±5%.

5. The method of claim 1, wherein the material layer is metallic.

6. The method of claim 1, wherein the corner surface includes a curved portion with a radius of curvature in a range from about 0.4 μm to about 4 μm.

7. The method of claim 1, wherein the patterning of the dielectric layer further comprises exposing a photoresist layer using a grayscale photomask that defines the opening.

8. The method of claim 1, wherein the dielectric layer is removed only by a dry etch process to form the opening.

9. The method of claim 8, wherein the dry etch process includes etching the dielectric layer and a photoresist layer formed on the dielectric layer such that the dielectric layer is etched at a first etch rate and the photoresist layer is etched at a second etch rate different than the first etch rate.

10. The method of claim 1, wherein the metal layer completely fills the opening.

11. The method of claim 1, wherein the metal layer partially fills the opening.

12. A method of forming an integrated circuit, comprising:
forming an electronic component over a semiconductor substrate, the electronic component having a metallic terminal;
forming a dielectric layer over the metallic terminal;
patterning the dielectric layer using a grayscale mask process to form an opening through the dielectric layer from a top surface of the dielectric layer to a top surface of the metallic terminal, the opening defining a sidewall of the dielectric layer having first and second sidewall portions, the first sidewall portion extending from the top surface of the dielectric layer to the second sidewall portion and the second sidewall portion extending to the top surface of the metallic terminal, the first sidewall portion having a first tapered slope and the second sidewall portion having a second tapered slope greater than the first tapered slope; and
depositing a metal routing layer over the dielectric layer, including a portion of the metal routing layer contacting the metallic terminal through the opening.

13. The method of claim 12, wherein the first tapered slope of the first sidewall portion is substantially planar.

14. The method of claim 13, wherein the first tapered slope of the first sidewall portion includes an angle of greater than about 30° relative to a surface normal of the top surface of the metallic terminal.

15. The method of claim 14, wherein the second tapered slope of the second sidewall portion includes an angle of less than about 15° relative to the surface normal.

16. The method of claim 12, wherein the first tapered slope of the first sidewall portion is curved having a radius of curvature in a range from about 0.4 μm to about 4 μm.

17. The method of claim 12, wherein the dielectric layer is removed only by a dry etch process to form the opening.

18. A semiconductor device, comprising:
an electronic device formed over a semiconductor substrate;
a dielectric layer disposed over the semiconductor substrate;
a metal routing layer disposed over the dielectric layer; and
one or more metal contacts connected to the metal routing layer and extending through the dielectric layer to one or more electrical terminals of the electronic device;
wherein at least one of the metal contacts includes a sidewall having a first sidewall portion and a second sidewall portion, the first sidewall portion extending from a top surface of the dielectric layer to the second sidewall portion and the second sidewall portion extending to a top surface of a corresponding one of the electrical terminals, the first sidewall portion having a first angle of about 30°or greater relative to a surface normal from the top surface of the corresponding one of the electrical terminals, and the second sidewall portion having a second angle of about 15°or less relative to the surface normal.

19. The semiconductor device of claim 18, wherein the first sidewall portion is substantially planar.

20. The semiconductor device of claim 18, wherein the first sidewall portion is curved.
